(19) United States
(12) Patent Application Publication
(10) Pub. No.: US 2025/0069952 A1
(43) Pub. Date: Feb. 27, 2025

(54) SYSTEMS AND METHODS FOR MITIGATING CRACK MEANDERING IN SEMICONDUCTOR DICING

(71) Applicant: Micron Technology, Inc., Boise, ID (US)

(72) Inventors: Vibhav Gupta, Singapore (SG); Wei Chang Mendoza Wong, Singapore (SG); Xinyun Chen, Singapore (SG); Raj K. Bansal, Boise, ID (US); Teng Leong Tan, Singapore (SG)

(21) Appl. No.: 18/788,846

(22) Filed: Jul. 30, 2024

Related U.S. Application Data
(60) Provisional application No. 63/534,082, filed on Aug. 22, 2023.

(51) Int. Cl. H01L 21/78; H01L 23/00

(52) U.S. Cl. CPC H01L 21/78; H01L 23/562

(57) ABSTRACT

Systems and methods for mitigating crack meandering, are disclosed herein. In some embodiments, the method includes forming a metallic layer over planned scribe regions of an upper surface of a wafer, then selectively patterning and/or etching the metallic layer to form a plurality of isolated lines over the planned scribe regions. The method can then include depositing a passivation material over the plurality of isolated lines. Adjacent isolated lines can be separated from each other by a small enough distance to disrupt the deposition process, thereby creating a gap in the passivation material between each of the adjacent isolated lines. The gaps and/or trenches formed in the top surface of the wafer by etching the passivation material through the gaps can help attract cracks during a stealth dicing process, thereby reducing the amount the cracks meander away from the planned scribe regions.

### CROSS-REFERENCE TO RELATED APPLICATION(S)

The present application claims priority to U.S. Provisional Patent Application No. 63/534,082, filed Aug. 22, 2023, the disclosure of which is incorporated herein by reference in its entirety.

### TECHNICAL FIELD

The present technology is generally related to semiconductor dicing, and more specifically to mitigating crack meandering in stealth dicing before grinding.

### BACKGROUND

Microelectronic devices, such as memory devices, microprocessors, and other electronics, typically include one or more semiconductor dies mounted to a substrate and encased in a protective covering. The semiconductor dies include functional features, such as memory cells, processor circuits, imager devices, interconnecting circuitry, etc. To meet continual demands on decreasing size, wafers, individual semiconductor dies, and/or active components are typically manufactured in bulk, singulated, and then stacked on a support substrate (e.g., a printed circuit board (PCB) or other suitable substrates). The stacked dies can then be coupled to the support substrate (sometimes also referred to as a package substrate) through bond wires in shingle-stacked dies (e.g., dies stacked with an offset for each die) and/or through substrate vias (TSVs) between the dies and the support substrate.

### BRIEF DESCRIPTION OF THE DRAWINGS

FIGS. 1A and 1B are a partially schematic cross-sectional view and top view, respectively, of a portion of a semiconductor wafer configured in accordance with some embodiments of the present technology.

FIG. 2 is a partially schematic cross-sectional view of a dicing region of a semiconductor wafer with crack mitigation features configured in accordance with some embodiments of the present technology.

FIG. 3 is a partially schematic cross-sectional view of a dicing region of a semiconductor wafer with crack mitigation features configured in accordance with further embodiments of the present technology.

FIGS. 4A-4H are partially schematic cross-sectional views of a semiconductor wafer during various stages of manufacturing in accordance with some embodiments of the present technology.

FIGS. 5A and 5B are partially schematic cross-sectional views of a semiconductor wafer during various stages of manufacturing in accordance with further embodiments of the present technology.

FIG. 6A is a partially schematic top view of a semiconductor wafer with crack attraction features configured in accordance with some embodiments of the present technology.

FIG. 6B is a partially schematic cross-sectional view of a semiconductor die after singulation in accordance with some embodiments of the present technology.

FIG. 7 is a partially schematic cross-sectional view of a semiconductor die after singulation in accordance with further embodiments of the present technology.

FIG. 8A is a flow diagram of a process for singulating a semiconductor wafer in accordance with some embodiments of the present technology.

FIG. 8B is a flow diagram of a process for manufacturing a semiconductor die in accordance with some embodiments of the present technology.

FIG. 9 is a schematic view of a system that includes a semiconductor die assembly configured in accordance with embodiments of the present technology.

The drawings have not necessarily been drawn to scale. Further, it will be understood that several of the drawings have been drawn schematically and/or partially schematically. Similarly, some components and/or operations can be separated into different blocks or combined into a single block for the purpose of discussing some of the implementations of the present technology. Moreover, while the technology is amenable to various modifications and alternative forms, specific implementations have been shown by way of example in the drawings and are described in detail below. The intention, however, is not to limit the technology to the particular implementations described.

### DETAILED DESCRIPTION

Specific details of several embodiments of semiconductor wafers, singulation thereof, and associated systems and methods are described below. The term “semiconductor device or die” generally refers to a solid-state device that includes one or more semiconductor materials. Examples of semiconductor devices include logic devices, memory devices, controllers, or microprocessors (e.g., central processing unit (CPU), graphics processing unit (GPU)), among others. Such semiconductor devices may include integrated circuits or components, data storage elements, processing components, and/or other features manufactured on semiconductor substrates. Further, the term “semiconductor device or die” can refer to a finished device or to an assembly or other structure at various stages of processing before becoming a finished functional device. Depending upon the context in which it is used, the term “substrate” can refer to a wafer-level substrate or to a singulated, die-level substrate. Also, a substrate may include a semiconductor wafer, a package support substrate, an interposer, a semiconductor device or die, or the like. A person having ordinary skill in the relevant art will recognize that suitable steps of the methods described herein can be performed at the wafer level or at the die level.

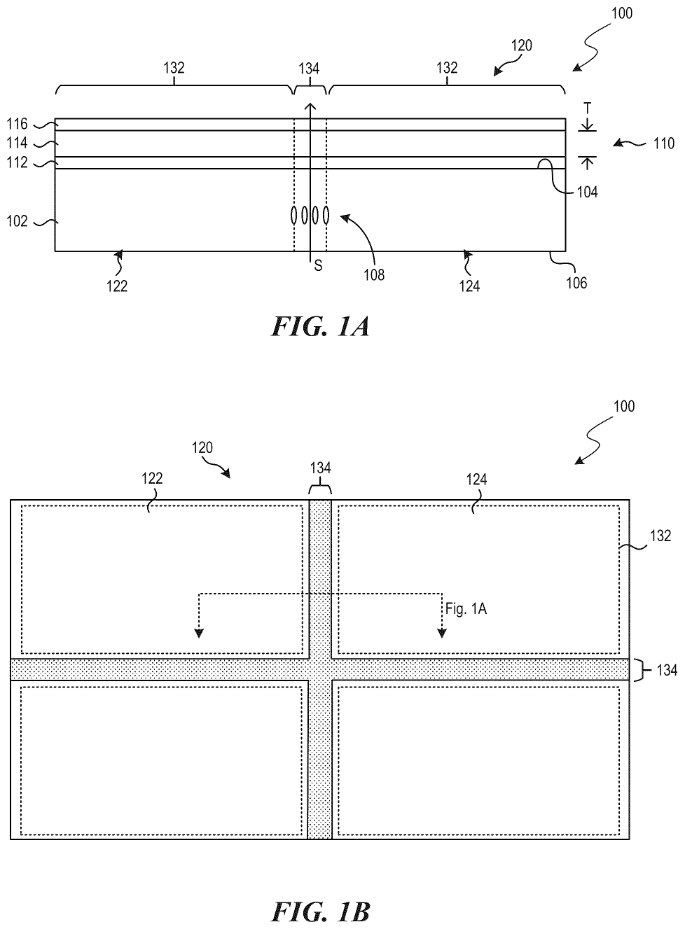

Further, unless the context indicates otherwise, structures disclosed herein can be formed using one or more semiconductor-manufacturing techniques. Materials can be deposited, for example, using chemical vapor deposition (CVD), physical vapor deposition (PVD), atomic layer deposition (ALD), spin coating, plating, and/or other suitable techniques. Similarly, materials can be removed, for example, using plasma etching, wet etching, chemical-mechanical planarization, or other suitable techniques. Some of the techniques may be combined with photolithography processes. A person skilled in the relevant art will also understand that the technology may have additional embodiments and that the technology may be practiced without several of the details of the embodiments described herein with reference to FIGS. 1A-9.

Systems and methods for mitigating crack migration during stealth dicing of a semiconductor wafer are disclosed herein. In some embodiments, the method includes forming a metallic layer over planned scribe regions of an upper surface of a wafer, then selectively patterning and/or etching the metallic layer to form a plurality of isolated lines over the planned scribe regions. The method can then include depositing a passivation material over the plurality of isolated lines. Adjacent isolated lines can be separated from each other by a small enough distance to disrupt the deposition process, thereby creating a gap in the passivation material between each of the adjacent isolated lines. The method can then include one or more additional deposition and/or etching steps on the passivation material to either clean and/or blend the passivation material with the gaps into additional layers on the wafer and/or to etch trenches into an upper surface of the wafer by etching through the passivation material. Once the gaps in the passivation material and/or the trenches are formed, the method can include stealth dicing the wafer and/or back grinding the wafer. Stealth dicing can include directing a laser beam (or other energy beam) toward a lower surface of the wafer (e.g., a back side of the wafer) to form one or more stress regions in the planned scribe regions, then causing cracks to propagate from the stress regions toward the surfaces of the wafer (e.g., by applying more energy with the laser, applying stress forces to the wafer, and/or the like). As discussed in more detail below, the gaps in the passivation material and/or the trenches can concentrate stress in the wafer and thereby attract any cracks propagating through the wafer. Accordingly, by forming the gaps and/or trenches only in planned scribe regions of the wafer, the method can help prevent the cracks from meandering away from the desired locations as they propagate.

In some embodiments, the wafer includes a plurality of die-formation regions. In such embodiments, the planned scribe regions can be positioned in a grid shape around the plurality of die formation regions. Further, in some embodiments, the method further includes forming one or more metallization layers on the upper surface of the wafer over the plurality of die formation regions. The metallization layers can be formed generally coplanar with at least a portion of the plurality of isolated lines. Further, in some embodiments, the metallization layers are formed generally simultaneously with the formation of the gaps and/or the trenches (e.g., during BEOL processes).

An example of the wafer resulting from various stages of the method can include a base substrate that has an upper surface with a plurality of scribe regions forming a grid on the upper surface and a circuitry region in each open location in the grid, as well as a plurality of circuitry layers carried by the upper surface of the base substrate. The plurality of circuitry layers can form a semiconductor die in each open location in the grid. Further, the wafer can include a plurality of crack attraction features carried by the base substrate over at least a portion of the plurality of scribe regions. In some embodiments, the plurality of isolated lines is at least partially coplanar with an uppermost circuitry layer from the plurality of circuitry layers. In some such embodiments, the crack attraction features form a perimeter around the uppermost circuitry layer from the plurality of circuitry layers in each semiconductor die on the base substrate.

The plurality of crack attraction features can be formed on and/or into a top surface of a second uppermost circuitry layer in the wafer. In some embodiments, the plurality of crack attraction features includes a plurality of isolated lines and a trench formed into the top surface of the second uppermost circuitry layer between each pair of adjacent isolated lines. In some embodiments, the plurality of crack attraction features includes a plurality of isolated lines and a passivation material deposited over the plurality of isolated lines. In such embodiments, the passivation material can include a gap positioned between each pair of adjacent isolated lines.

In some embodiments, the wafer includes one or more cracks extending from a lower surface of the base substrate to a top surface of an uppermost circuitry layer and between two adjacent isolated lines in the plurality of crack attraction features (e.g., after a stealth dicing process on the wafer). The cracks can be used to singulate individual semiconductor dies from the wafer. As a result of the singulation and the processes discussed above, each singulated semiconductor die can include a base substrate that has a central region and a peripheral region, as well as one or more circuitry layers formed over the central region. An uppermost circuitry layer can include one or more routing structures and/or metallization layers establishing signal route lines for the semiconductor device. The semiconductor device can also include one or more isolated lines carried by the peripheral region of the upper surface, wherein the one or more isolated lines are at least partially coplanar with the uppermost circuitry layer. Further, because the isolated lines are used for the singulation process, rather than the operation of the semiconductor die, none of the one or more isolated lines is typically electrically coupled to another structure in the semiconductor device.

In some embodiments, two or more isolated lines are left after singulation. In various such embodiments, the semiconductor device can include a passivation layer formed over the isolated lines. The passivation layer includes a gap positioned between each pair of adjacent isolated lines and/or a trench formed into a second uppermost circuitry layer (or the base substrate) between each pair of adjacent isolated lines. In some embodiments, the semiconductor device includes a shape resulting from a singulation process through a crack propagating through a gap (or trench) along the peripheral-most sidewall. As a result, for example, the semiconductor device can have a concave shape along at least a portion of a peripheral-most sidewall corresponding to a gap (or trench) that was bifurcated by a crack during the singulation process.

Additional details on the systems and methods for mitigating crack migration, resulting semiconductor devices, and associated systems and methods, are set out below. For ease of reference, semiconductor assemblies (and their components) are sometimes described herein with reference to front and back, top and bottom, upper and lower, upwards and downwards, and/or horizontal plane, x-y plane, vertical, or z-direction relative to the spatial orientation of the embodiments shown in the figures. It is to be understood, however, that the semiconductor assemblies (and their components) can be moved to, and used in, different spatial orientations without changing the structure and/or function of the disclosed embodiments of the present technology.

Further, although the crack attracting features disclosed herein are primarily discussed in the context of stealth dicing to singulate semiconductor dies in a wafer, one of skill in the art will understand that the scope of the technology is not so limited. For example, the systems and methods disclosed herein can also be deployed to help mitigate crack propagation in various other settings that involve cutting through semiconductor components (e.g., to singulate components of a semiconductor device (e.g., an interposer board) manufactured on a wafer).

FIGS. 1A and 1B are a partially schematic cross-sectional view and top view, respectively, of a portion of a semiconductor wafer 100 configured in accordance with some embodiments of the present technology. As illustrated in FIG. 1A, the semiconductor wafer 100 (“wafer 100”) can include a base substrate 102, and one or more layers of circuitry 110 carried by a first surface 104 (e.g., an upper surface) of the base substrate 102. In the illustrated embodiment, the one or more layers of circuitry 110 (“circuitry layers 110”) include a first circuitry layer 112, a second circuitry layer 114, and a third circuitry layer 116. However, it will be understood that, in various other embodiments, the circuitry layers 110 can include one, two, four, five, and/or any other suitable number of layers. The circuitry layers 110 can make up a portion (or all) of the electrical components for a plurality of semiconductor dies 120 on the wafer 100 (two illustrated in FIG. 1A, referred to as a first die 122 and a second die 124). For example, the first circuitry layer 112 can include complementary metal-oxide-semiconductor (CMOS) circuitry, such as one or more gates for the plurality of semiconductor dies 120 (“dies 120”); the second circuitry layer 114 can include array circuitry for the dies 120; and the third circuitry layer 116 can include various back-end-of-line structures (e.g., one or more metallization lines establishing route lines for the array circuitry and/or the CMOS circuitry.

In some embodiments, the circuitry layers 110 can be sequentially deposited and/or formed over the base substrate 102. For example, a first series of semiconductor processes can form CMOS circuitry in the first circuitry layer, then a second series of semiconductor processes can form array circuitry in the second circuitry layer 114, and so on. However, the technology disclosed herein is not so limited. In some embodiments, each of the circuitry layers 110 can be created on a separate wafer, then stacked and bonded together to form the wafer 100 of FIG. 1A. In some such embodiments, each of the circuit layers 110 is bonded through a hybrid bond, resulting in a generally continuous substrate in the wafer 100.

As further illustrated in FIG. 1A, the wafer 100 can include a plurality of die regions 132 and one or more scribe regions 134 (one illustrated in FIG. 1A). The first and second dies 122, 124 can be formed in the die regions 132 (sometimes also referred to herein as “die formation regions,” “circuitry regions,” and/or the like) of the wafer 100 and separated by the scribe region 134 (sometimes also referred to herein as “dicing regions,” “dicing sections,” “designated scribe regions,” “singulation lanes,” “dicing lanes,” “streets,” and/or the like). As illustrated in FIG. 1B, the scribe regions 134 can be positioned in and/or form a grid the wafer 100. The die regions 132 are positioned in the open regions of the grid. As a result, for example, when a dicing process is performed on the scribe regions 134, the wafer 100 is split (or partially split), to singulate the dies 120.

In a specific example, explained with reference to FIG. 1A, a stealth dicing process can be performed on the wafer 100 through a second surface 106 (e.g., a lower surface) of the base substrate 102. In a stealth dicing process, a laser is directed toward the second surface 106 of the base substrate 102 in the scribe regions 134. The laser generates a crack (or multiple cracks) in the base substrate 102 (sometimes also referred to as a “split,” a “kerf,” and/or the like) that is can then be propagated toward the first surface 104 and through the circuitry layers 110. Stealth dicing typically requires less room for the scribe regions 134 than other methods of dicing (e.g., with a mechanical blade), allowing more die regions 132 to be fit into a single wafer. Additionally, stealth dicing typically causes less damage to the sidewalls of the resulting dies, thereby improving the strength and life span of the resulting dies.

In some embodiments, the wafer 100 can include various features to help crack formation and/or propagation to improve the stealth dicing process. For example, as illustrated in FIG. 1A, the base substrate 102 can include a plurality of defects 108 (e.g., metallic formations) that attract and direct the crack propagation along a singulation path S through the wafer 100. Once the crack has started along the singulation path S, the crack propagates along a generally straight line through the base substrate 102. However, the crack can meander away from the singulation path S once it reaches the circuitry layers 110. When the thickness of the circuitry layers 110 is sufficiently thin, the crack cannot meander far enough to undermine one of the dies 120 (e.g., by propagating into one of the die regions 132 and damaging electronics therein, causing a chip in the upper surface of the die that undermines the strength of the die, and/or the like). Accordingly, the crack meandering is not a problem for the stealth dicing process when the circuitry layers 110 are thin.

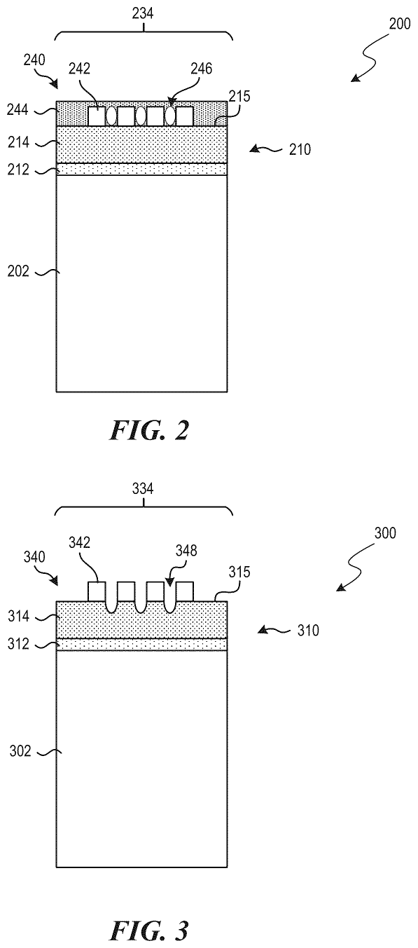

Continual demands for increased performance capabilities of each of the dies 120, however, has resulted in an increase in the electronics formed in the circuitry layers 110 and a corresponding increase in thickness. In particular, the demands have caused an increase in the thickness T of the array layers (e.g., the second circuitry layer 114 in FIG. 1A) in the wafer 100. With the increase in the thickness T, cracks can meander farther from the singulation path S, resulting in damage to the electronics in one or more of the circuitry layers 110 and/or causing chips in the upper surface and/or sidewalls of the dies 120. As a result, crack meandering can undermine the benefits of stealth dicing by reducing the throughput of the manufacturing process when singulating the wafer 100. FIGS. 2-8 illustrate various examples of features and processes that can be used to help reduce crack meandering as the thickness T continues to increase.

FIG. 2 is a partially schematic cross-sectional view of a dice region 234 of a semiconductor wafer 200 configured in accordance with some embodiments of the present technology. As illustrated in FIG. 2, the semiconductor wafer 200 (“wafer 200”) is generally similar to the wafer 100 described above with reference to FIG. 1A. For example, the wafer 200 includes a base substrate 202, as well as one or more circuitry layers 210 carried by the base substrate 202 (two illustrated in FIG. 2, referred to as a first circuitry layer 212 and a second circuitry layer 214). However, in the illustrated embodiment, the wafer 200 includes crack attraction features 240 formed over a top surface 215 of the second circuitry layer 214. In the illustrated embodiment, the crack attraction features 240 (sometimes also referred to herein as “crack guides,” “singulation guides,” “crack meandering mitigation features,” “attraction features,” and/or the like) include a plurality of isolated lines 242 formed on the top surface 215 and a passivation material 244 formed over the isolated lines 242. The isolated lines 242 can include a metallic material (e.g., copper, aluminum, gold, and/or the like), an insulation material (e.g., a dielectric, a polymer, and/or another suitable substrate), and/or any other suitable material. However, because the isolated lines 242 are used to help guide cracks during singulation, the isolated lines may not be electrically coupled to another structure in the wafer 200. The passivation material can be any suitable passivation oxide and/or passivation nitride.

As further illustrated in FIG. 2, the passivation material 244 can include gaps 246 between adjacent pairs of the isolated lines 242. As discussed in more detail below, the gaps 246 (sometimes also referred to herein as “channels,” “voids,” and/or the like) can result from the deposition process of the passivation material 244 over the isolated lines 242. As a result, the gaps 246 can be filled with air and/or another gas ambient around the wafer 200 during manufacturing. Further, the gaps 246 can have relatively sharp edges (e.g., the lowermost edge and the uppermost edge of each of the illustrated gaps 246) that concentrate stress. In turn, the concentration of stress can help attract cracks propagating through the wafer 200. As a result, the gaps 246 help prevent the crack from meandering away from a straight line through the wafer 200 (e.g., the singulation path S of FIG. 1A, beginning at one or more target locations, from one or modified structures in the base substrate 202, and the like).

In some embodiments, the crack attraction features 240 are formed at least partially coplanar with one or more additional circuitry layers formed over the second circuitry layer 214 (e.g., the third circuitry layer 116 of FIG. 1A). Purely by way of example (and as discussed below), the isolated lines 242 can be at least partially coplanar with one or more routing structures and/or metallization layers formed in BEOL processes over the second circuitry layer 114. In some such embodiments, the crack attraction features 240 are formed during the BEOL processes and/or are formed by similar processing steps.

FIG. 3 is a partially schematic cross-sectional view of a dicing region 334 of a semiconductor wafer 300 configured in accordance with further embodiments of the present technology. As illustrated in FIG. 3, the semiconductor wafer 300 (“wafer 300”) is generally similar to the wafer 200 described above with reference to FIG. 2. For example, the wafer 300 includes a base substrate 302, first and second circuitry layers 312, 314 carried by the base substrate 302 (referred to collectively as “circuitry layers 310”), and crack attraction features 340 formed over a top surface 315 of the second circuitry layer 314. Further, the crack attraction features 340 include a plurality of isolated lines 342 formed on the top surface 315.

However, in the illustrated embodiment, the passivation material has been etched off the top surface 315. Further, the etching process has formed trenches 348 in the top surface 315 of the second circuitry layer 314 between adjacent pairs of the isolated lines 342 (e.g., because the etching process reaches the top surface 315 quickly where the gaps were present in the passivation material). Similar to the gaps 246 of FIG. 2, the trenches 348 have relatively sharp edges that concentrate stress and, as a result, attract cracks propagating through the wafer 300. Further, the trenches 348 provide a thinner point in the wafer 300 for the cracks to propagate through, thereby acting as a path of less resistance to crack propagation. Still further, the trenches 348 can be aligned with various singulation paths that may be taken by the crack through the base substrate 302 (e.g., vertically aligned with target locations, modified structures in the base substrate 302, and the like). As a result, the trenches 348 can help prevent the crack from meandering away from the straight singulation path through the wafer 300 (e.g., the singulation path S of FIG. 1A).

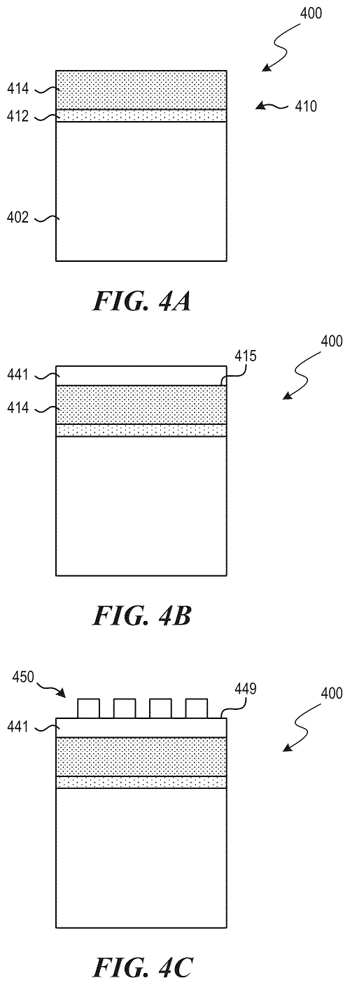

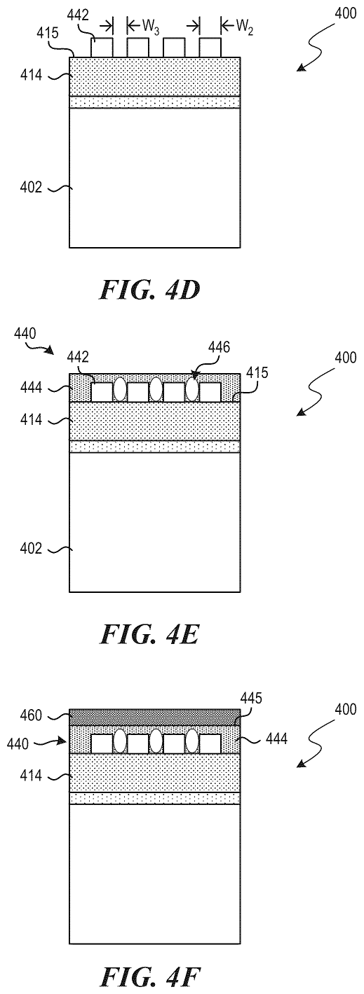

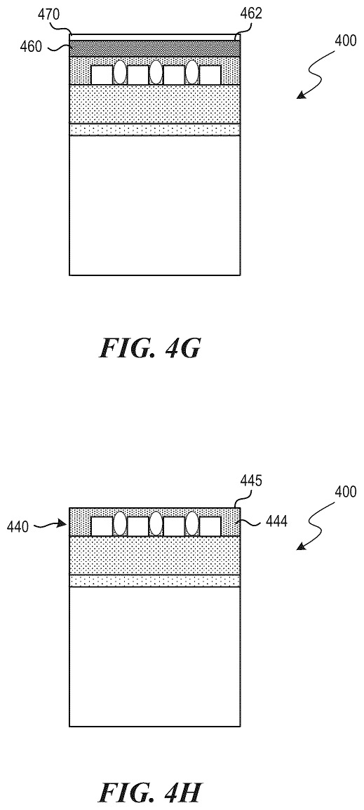

FIGS. 4A-4H are partially schematic cross-sectional views of a dicing region of a semiconductor wafer 400 during various stages of manufacturing crack attraction features in accordance with some embodiments of the present technology. As illustrated in FIG. 4A, the semiconductor wafer 400 (“wafer 400”) begins generally similar to the wafers 200, 300 discussed above with reference to FIGS. 2 and 3 without any the crack attraction features. For example, the wafer 400 includes a base substrate, as well as a plurality of circuitry layers 410 formed over the base substrate 402 (two illustrated in FIG. 4A, referred to individually as a first circuitry layer 412 and a second circuitry layer 414).

FIG. 4B illustrates the wafer 400 after a temporary layer 441 is deposited over a top surface 415 of the second circuitry layer 414. In some embodiments, the temporary layer 441 is a metal layer (e.g., a copper layer, an aluminum layer, a gold layer, and/or the like). In such embodiments, the temporary layer 441 can be deposited by a sputtering process and/or any other suitable process. In various other embodiments, the temporary layer 441 can be a dielectric material, a polymer, a mold material, and/or any other suitable material that can be patterned and/or selectively etched.

FIG. 4C illustrates the wafer 400 after a photoresist material 450 is deposited and patterned over an upper surface 449 of the temporary layer 441. As illustrated, the patterning in the photoresist material 450 selectively protects portions of the upper surface 449. The unprotected portions of the temporary layer 441 can then be selectively etched through the openings in the photoresist material 450. Afterward, any remaining portions of the photoresist material 450 can be stripped away. FIG. 4D illustrates the wafer 400 after the etching and stripping processes.

As illustrated in FIG. 4D, the etching and stripping processes on the wafer 400 form isolated lines 442 the top surface 415 of the second circuitry layer 414. In the illustrated embodiment, each of the isolated lines 442 has a first width W₁ and is spaced apart from any adjacent isolated lines by a second width W₂. The first width W₁ can be based at least partially on the number of isolated lines 442 that will be formed over the dicing region, the width of the dicing region, the portion of the dicing region that will be covered with the isolated lines 442, and/or various other suitable factors. In various specific, non-limiting examples, the first width W₁ can be between about 1 micrometer (μm) and about 10 μm, between about 2 μm and about 5 μm, or can be about 4 μm. The second width W₂ can be based on the first width W₁ and a scale necessary to ensure gaps (e.g., the gaps 246 discussed above with reference to FIG. 2) are formed when a passivation material is deposited over the isolated lines 442. In various specific, non-limiting examples, the second width W₂ can be between about 1 μm and about 8 μm, between about 2 μm and about 4 μm, or can be about 3 μm.

In some embodiments, the isolated lines 442 are positioned such that each of the isolated lines 442 is generally vertically aligned with a corresponding defect in the base substrate 402 and/or one or more corresponding target locations on the base substrate 402. The alignment can help ensure that the gaps and/or trenches are later formed in alignment with the spaces between the defects and/or in alignment with the target locations, thereby providing various straight, vertical paths through the wafer 400 for a crack to propagate.

FIG. 4E illustrates the wafer 400 after a first passivation material 444 is deposited over the top surface 415 of the second circuitry layer 414 and the isolated lines 442. In various embodiments, the first passivation material 444 can be deposited by an atomic layer deposition process, a spin-coating process, electrochemical deposition, and/or any other suitable process. During any of the suitable processes, the isolated lines 442 can disrupt the deposition in the spaces between adjacent pairs of the isolated lines 442, resulting in the formation of gaps 446 in the first passivation material 444. The height and/or width of the gaps can be dependent on the second width W₂ (FIG. 4D) of the space between the isolated lines 442, the deposition process used, and/or various other factors. In the illustrated embodiment, the gaps 446 have a width generally equal to the second width W₂ (e.g., extending fully between adjacent pairs of the isolated lines 442) and a height that is larger than a height of the isolated lines 442 (e.g., resulting in the gaps 446 having an upper edge at an elevation above an uppermost surface of the isolated lines 442). In various other embodiments, the width of the gaps can be less than the second width W₂ and/or a height that is equal to and/or less than the height of the isolated lines 442. In each of the embodiments, the gaps 446 can have a relatively sharp lower edge (e.g., a sharp curve on the lowermost edge) that concentrates stress in the wafer 400 and attracts cracks propagating therethrough.

In some embodiments, the first passivation material 444 is limited to the dicing region around the crack attraction features 440. In other embodiments, the first passivation material 444 can extend over the die regions of the wafer 400 (e.g., the die regions 132 of FIG. 1A) to form an insulating dielectric between the second circuitry layer 414 and one or more additional circuitry layers formed over the second circuitry layer 414 (e.g., the third circuitry layer 116 of FIG. 1A).

In some embodiments, the manufacturing process can move onto processing other features of the wafer 400 after depositing the first passivation material 444 to form the crack attraction features 440. For example, once the gaps 446 are formed, the manufacturing process can proceed directly to a stealth dicing process and utilize the gaps 446 to attract cracks propagating through the wafer 400. In some embodiments, the manufacturing process can complete one or more additional steps to complete manufacturing of the crack attraction features 440.

For example, FIG. 4F illustrates the wafer after a second passivation material 460 is deposited on an upper surface 445 of the first passivation material 444 from the crack attraction features 440. The second passivation material 460 can provide an additional passivation layer over the crack attraction features 440 while one or more stages of BEOL processing are performed on the wafer 400 (e.g., to form a third circuitry layer over the die regions of the wafer 400). In some such embodiments, the first passivation material 444 is an oxide-based passivation material (e.g., silicon dioxide) while the second passivation material is a nitride-based passivation material (e.g., silicon nitride). Additionally, or alternatively, the second passivation material 460 can be part of an insulating dielectric between the second circuitry layer 414 and one or more additional circuitry layers formed over the second circuitry layer 414 (e.g., during the BEOL processes). In other embodiments, the second passivation material 460 can be limited to the dicing region over the crack attraction features 440.

FIG. 4G illustrates the wafer after a polyimide layer 470 is deposited over an upper surface 462 of the second passivation material 460. In some embodiments, the polyimide layer 470 can be formed on the second passivation material 460 over the crack attraction features 440 to protect the crack attraction features during various BEOL processes. In some embodiments, the polyimide layer 470 can be deposited during one of the BEOL processes (e.g., as an insulation layer between one or more metallization layers in a third circuitry layer and/or over a top surface of the third circuitry layer). A patterned material (e.g., leaky chrome) can then be formed over the polyimide layer 470 to selectively strip the polyimide layer 470 and expose the second passivation material 460.

As illustrated in FIG. 4H, the second passivation material 460 can then be etched away to re-expose the upper surface 445 of the first passivation material 444. The re-exposure can help ensure that the wafer 400 is relatively thin over the crack attraction features 440, which can help facilitate the singulation of the wafer 400. Additionally, or alternatively, the re-exposure can help prepare the wafer 400 for later BEOL processes.

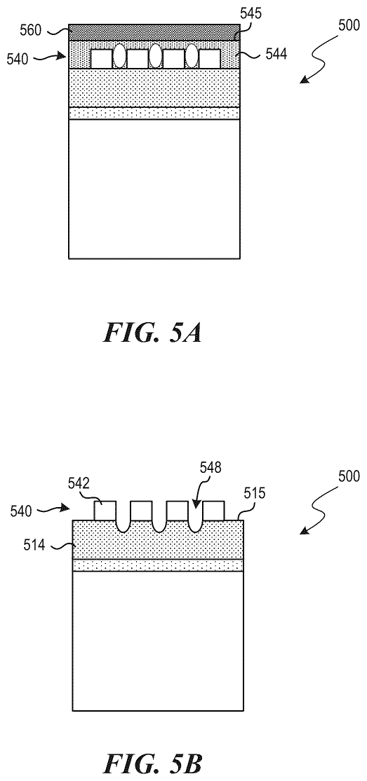

FIGS. 5A and 5B are partially schematic cross-sectional views of a dicing region of a semiconductor wafer 500 during various stages of manufacturing in accordance with further embodiments of the present technology. The stage of manufacturing illustrated in FIG. 5A can begin after the manufacturing processes described above with reference to FIGS. 4A-4E have deposited a first passivation material 544 over a second circuitry layer 514 in the wafer 500. In particular, FIG. 5A illustrates the wafer 500 after a second passivation material 560 is deposited on an upper surface 545 of the first passivation material 544. The second passivation material 560 can be generally similar to the second passivation material 460 discussed above with reference to FIG. 4F.

However, the processes illustrated in FIGS. 5A and 5B do not include forming any polyimide or other barrier materials over the second passivation material 560 during the production of the crack attraction features 540. As a result, as illustrated in FIG. 5B, a subsequent etching process can remove both the first and second passivation materials 544, 560 and expose a top surface 515 of the second circuitry layer 514. Further, because the first passivation material 544 (FIG. 5A) was formed around isolation lines 542 generally similar to the isolated lines 442 discussed above with reference to FIGS. 4C and 4D, the first passivation material 544 included gaps between the isolation lines 542. In turn, the gaps allow the etching process to act on the top surface 515 of the second circuitry layer 514, thereby forming trenches 548 in the top surface 515 between adjacent pairs of the isolation lines 542. Similar to the gaps discussed above, the trenches 548 can have relatively sharp curves in their lower edges that concentrate stress in the wafer 500. In turn, the concentration of stress can help attract cracks propagating through the wafer 500, thereby helping mitigate problems associated with crack meandering.

Additionally, because the trenches 548 are formed into the top surface 515 of the second circuitry layer 514, the trenches 548 can create relatively thin portions of the wafer 500 (e.g., as compared to areas without the trenches 548). The relatively thin portions can present a path of least resistance to a crack propagating through the wafer 500, thereby further attracting the crack towards the trenches 548.

It will be understood that, while the gaps 446 and/or the trenches 548 have been described herein as being formed in a BEOL layer of circuitry, the gaps 446 and/or the trenches 548 can be formed in any other suitable layer using manufacturing processes similar to those discussed above with reference to FIGS. 4A-5B. For example, gaps and/or trenches can be formed in an intermediate layer to further improve the crack-guiding function of the gaps and/or trenches (e.g., when there are a large number of circuitry layer). In another example, the gaps and/or trenches can be formed in an additional layer over the BEOL layer (or additional wafer bonded to the BEOL layer). The additional layer (or wafer) can be useful, for example, for wafer-wafer bonding examples (e.g., where circuitry layers are manufactured on individual wafers, then stacked and bonded).

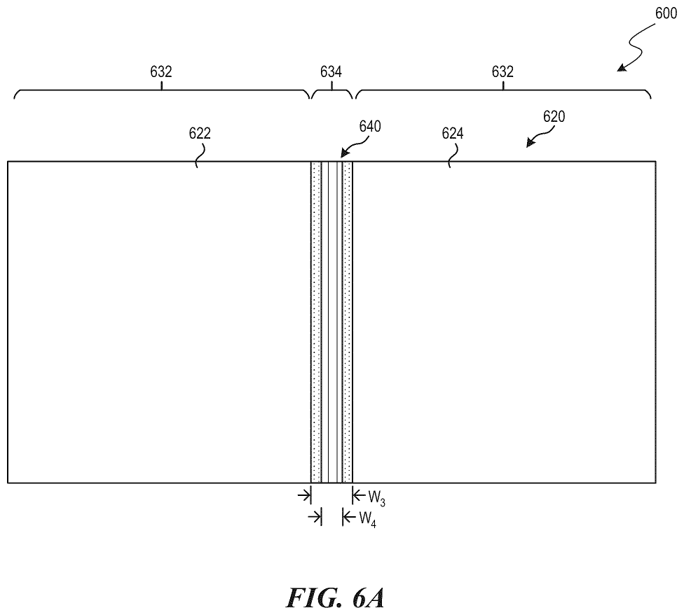

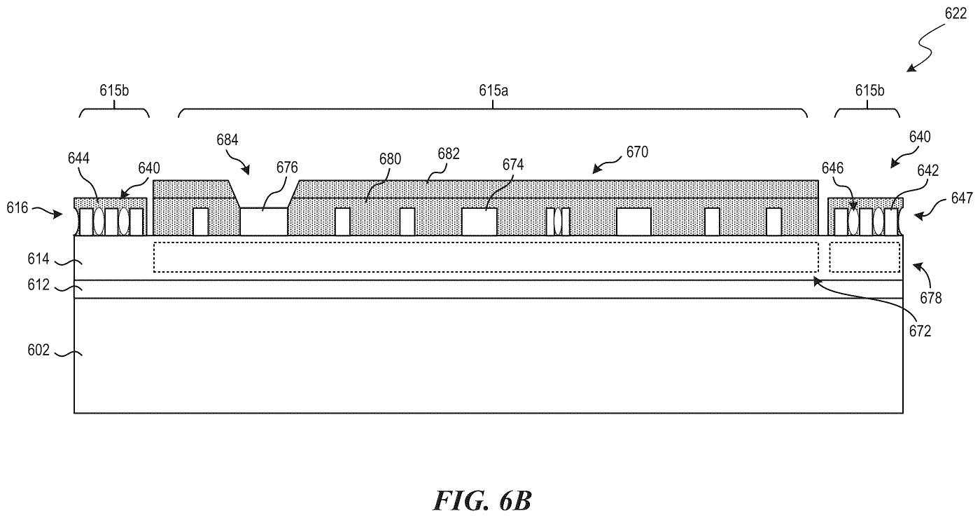

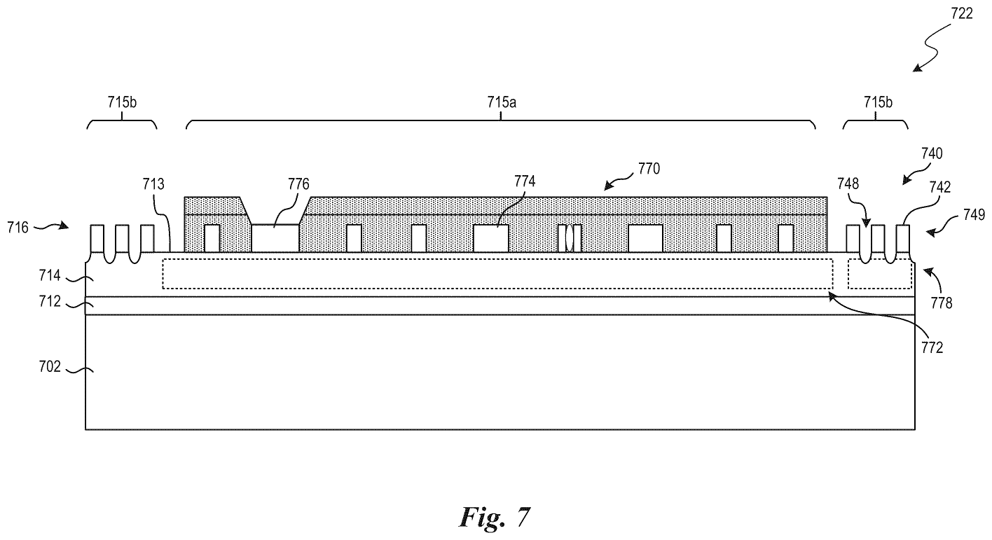

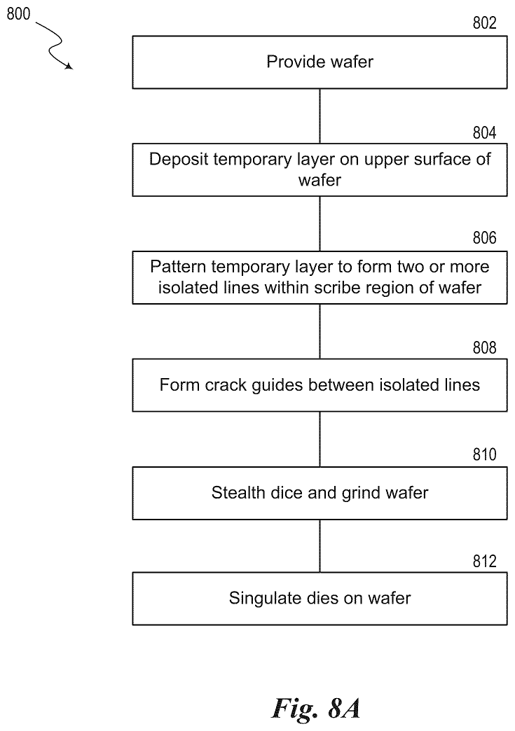

FIG. 6A is a partially schematic top view of a portion of a semiconductor wafer 600 configured in accordance with some embodiments of the present technology. Similar to the wafer 100 described above with reference to FIGS. 1A and 1B, the semiconductor wafer 600 (“wafer 600”) can include a plurality of die regions 632 (two illustrated in FIG. 6A) and one or more scribe regions 634 (one illustrated in FIG. 6A) positioned between each of the die regions 632. Further, the wafer 600 includes a plurality of semiconductor dies 620 (shown schematically) individually formed in a corresponding one of the die regions 632. However, in the illustrated embodiment, the wafer 600 also includes crack attraction features 640 formed over a portion of the scribe region 634. As discussed above, the crack attraction features 640 can help mitigate crack meandering during a stealth dicing process to singulate first and second semiconductor dies 622, 624 in the wafer 600.

As further illustrated in FIG. 6A, the crack attraction features 640 may not formed over all of the scribe region 634. For example, the scribe region 634 can have a third width W₃ while the crack attraction features 640 have a fourth width W₄ that is less than the third width W₃. The third width W₃ of the scribe region 634 can be generally defined by a distance between critical electronics in the first and second semiconductor dies 622, 624 and/or a width of the footprint of various sacrificial electronics on the wafer 600 (e.g., testing transistors, resistors, and/or other suitable components that do not perform a function in the first and second semiconductor dies 622, 624; alignment marks used during wafer-to-wafer bonding; and/or the like). By positioning the crack attraction features 640 over only a portion of the third width W₃, the crack attraction features 640 can provide a margin of error for cracks that still meander outside of the footprint of the fourth width W₄. For example, a crack that meanders just outside of the fourth width W₄ of the crack attraction features 640 may still not meander out of the third width W₃ of the scribe region 634. As a result, the crack will not damage the critical electronics in the first and second semiconductor dies 622, 624. In various embodiments, the fourth width W₄ can be between about 45 percent of the third width W₃ and about 85 percent of the third width W₃, or between about 60 percent of the third width W₃ and about 70 percent of the third width W₃.

FIG. 6B is a partially schematic cross-sectional view of the first semiconductor die 622 after singulation from the wafer 600 of FIG. 6A in accordance with some embodiments of the present technology. As illustrated in FIG. 6B, the first semiconductor die 622 can include a base substrate 602, a first circuitry layer 612 formed over the base substrate 602, a second circuitry layer 614 formed over the first circuitry layer 612, and a third circuitry layer 616 formed over the second circuitry layer 614. Further, the first semiconductor die 622 includes crack attraction features 640 formed over peripheral region 615b of the second circuitry layer 614 coplanar with the third circuitry layer 616. In the illustrated embodiment, the crack attraction features 640 include a plurality of isolated lines 642 embedded in a first passivation material 644 and gaps 646 formed in the passivation material first 644 between adjacent ones of the isolated lines 642. As discussed above, the gaps 646 can concentrate stress on their sharp contours, thereby attracting cracks through the crack attraction features 640 as they propagate through the wafer 600 (FIG. 6A). As a result, for example, the first semiconductor die 622 includes an intersected gap 647 on a peripheral most edge of the third circuitry layer 616. In the illustrated embodiment, the intersected gap 647 defines a concave shape along at least a portion of a peripheral-most sidewall of the passivation material 644.

As further illustrated in FIG. 6B, the first, second, and third circuitry layers 612, 614, 616 can include various internal electronics 670 relevant to the type of semiconductor dies that were formed on the wafer 600 of FIG. 6A. In the illustrated embodiment, the internal electronics 670 include critical array structures 672 (shown schematically) formed in the second circuitry layer 614, one or more routing structures 674, an external bond pad 676, and sacrificial fabrication structures 678 (shown schematically, sometimes also referred to herein as “sacrificial components”). The critical array structures 672 are formed in a central region 615a of the second circuitry layer 614 (e.g., away from the scribe regions 634 of FIG. 6A). The routing structures 674 (e.g., a redistribution layer, one or more metallization structures, and the like) are formed in a second passivation material 680 (e.g., one or more layers of dielectric, polyimide, metallization, and/or other suitable materials) over a central portion of the third circuitry layer 616 and define routing lines in the first semiconductor die 622. Because the third circuitry layer 616 is coplanar with the crack attraction features 640, one or more of the routing structures 674 can be generally coplanar with the isolated lines 642.

In the illustrated embodiment, the circuitry layer 616 includes a third passivation material 682 deposited over the second passivation layer 680. The external bond pad 676 is exposed through an opening 684 in the second and third passivation layers 680, 682 to provide a connection point for the first semiconductor die 622 to be coupled to one or more external components (e.g., another semiconductor die, a package substrate, and/or the like). The third passivation material helps insulate and/or protect the routing structures 674 in the circuitry layer 616. However, it will be understood that, in some embodiments, the circuitry layer 616 does not include the third passivation material 682. Additionally, or alternatively, the first and second passivation materials 644, 680 can be generally continuous (or continuous), for example when the 640 crack attraction features are formed by the same process as the routing structures 674. In some embodiments, the passivation material 644 can abut the second passivation materials 680 around a boundary between the peripheral region 615b and the central region 615a, rather than being spaced apart by a gap.

The sacrificial fabrication structures 678 are formed in the peripheral region 615b of the second circuitry layer 614. As discussed above, the sacrificial fabrication structures 678 can include testing circuits, alignment marks, and/or other structures that are used during wafer-level fabrication. However, the sacrificial fabrication structures 678 do not contribute to the functionality of the first semiconductor die 622. Accordingly, it does not impact the functionality of the first semiconductor die 622 if the sacrificial fabrication structures 678 are split and/or otherwise broken during singulation. Thus, the sacrificial fabrication structures 678 can be formed in the scribe regions 634 of the wafer 600 (FIG. 6A) to reduce their footprint in singulated dies. As a result, the crack attraction features 640 can be formed over at least a portion of the sacrificial fabrication structures 678 (e.g., vertically aligned with at least a portion of the sacrificial fabrication structures 678) and can attract the crack through the sacrificial fabrication structures 678 during singulation.

FIG. 7 is a partially schematic cross-sectional view of a semiconductor die 722 after singulation in accordance with further embodiments of the present technology. As illustrated in FIG. 7, the semiconductor die 722 is generally similar to the first semiconductor die 622 discussed above with reference to FIG. 6A. For example, the semiconductor die 722 includes a base substrate 702, a first circuitry layer 712 formed over (or bonded to) the base substrate 702, a second circuitry layer 714 formed over (or bonded to) the first circuitry layer 712, and a third circuitry layer 716 formed over (or bonded to) the second circuitry layer 714. Further, the first, second, and third circuitry layers 712, 714, 716 can include various internal electronics 770 relevant to the type of semiconductor component the semiconductor die 722 is (e.g., logic die, memory die, controller die, and/or the like). In the illustrated embodiment, the internal electronics 770 include array structures 772 (shown schematically) formed in a central region 715a of the second circuitry layer 714, one or more routing structures 774 formed in the third circuitry layer 716 (e.g., one or more metallization layers), an external bond pad 776 exposed at an outermost surface of the third circuitry layer 716, and sacrificial fabrication structures 778 (shown schematically) formed in the peripheral region 715b of the second circuitry layer 714.

Still further, the semiconductor die 722 includes crack attraction features 740 formed over the peripheral regions 715b of the second circuitry layer 714 generally coplanar with the third circuitry layer 716 (and one or more of the routing structures 774 therein). In the illustrated embodiment, however. the crack attraction features 740 include a plurality of isolated lines 742 and trenches 748 formed in the top surface 713 of the second circuitry layer 714 between adjacent ones of the isolated lines 742. As discussed above, the trenches 748 can concentrate stress on their sharp contours, thereby attracting cracks through the crack attraction features 740 as they propagate through a wafer (e.g., the wafer 600 of FIG. 6A). As a result, as further illustrated in FIG. 7, the semiconductor die 722 can include an intersected trench 749 on a peripheral most edge of the third circuitry layer 716.

FIG. 7 further illustrates a consequence of forming the trenches 748 in the top surface 713 of the second circuitry layer 714. Because the trenches 748 and the sacrificial fabrication structures 778 are each formed in the peripheral region 715b of the second circuitry layer 714, the trenches 748 can cut through one or more of the sacrificial fabrication structures 778. However, because the sacrificial fabrication structures 778 are not active in the operation of the semiconductor die 722, the damage to the sacrificial fabrication structures 778 does not undermine the performance of the semiconductor die 722.

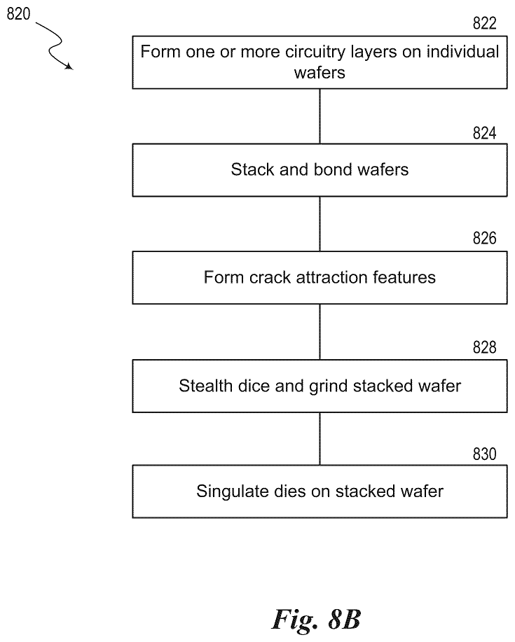

FIG. 8A is a flow diagram of a process 800 for singulating a semiconductor wafer in accordance with some embodiments of the present technology. The process 800 can be implemented by one or more manufacturing apparatuses to complete production of semiconductor dies (or other suitable components) in a wafer-level process. The process 800 begins at block 802 by providing a wafer (e.g., as partially illustrated in FIG. 4A). The wafer can be prefabricated by one or more other processes to have one or more layers of circuitry (e.g., CMOS circuitry and array circuitry) formed over a base substrate. In some embodiments, providing the wafer includes performing various front-end-of-line processes on a wafer and/or completing one or more wafer-to-wafer bonding processes.

At block 804, the process 800 can include depositing a temporary layer on an upper surface of the wafer (e.g., as illustrated in FIG. 4B). The temporary layer can be a metallic material that includes copper, aluminum, tin, gold, and/or any other suitable material. In various such embodiments, the metallic material can be deposited by a sputtering process and/or any other suitable process. In some embodiments, the process 800 includes forming a layer from a non-metallic material, such as an insulation material, mold material, polymer, and/or another suitable material that can be selectively patterned and/or etched after being deposited.

At block 806, the process 800 includes selectively patterning and/or etching the temporary layer to form isolated lines within a scribe region of the wafer. In some embodiments, patterning the temporary layer includes depositing a photoresist mask over the temporary layer, patterning the photoresist mask, and etching the temporary layer through the photoresist mask. As discussed above, the isolated lines can be spaced apart by a distance that is configured to interfere with later deposition processes (e.g., such that a spin coating process is pinched off between the isolated lines). Further, in various embodiments, the isolated lines can cover only a portion of the scribe region. As a result, for example, the isolated lines, and the crack guides formed between them, can help attract cracks only toward a center of the scribe region.

At block 808, the process 800 includes forming the crack guides between each pair of adjacent isolated lines. The crack guides (e.g., also referred to herein as crack attracting features) can be gaps formed in a passivation material between the pairs of adjacent isolated lines (e.g., as illustrated in FIG. 2) and/or trenches formed in a top surface of the wafer (e.g., as illustrated in FIG. 3). As discussed above with reference to FIGS. 4D-5B, forming the crack guides can include depositing one or more passivation materials and/or one or more etching processes (selective or complete) of the passivation materials. In some embodiments, the process 800 at block 808 can include forming a variety of the crack guides on the wafer. For example, the process 800 can include forming gaps in a passivation material over a first portion of the scribe regions in the wafer and trenches in an upper surface of the wafer in a second portion of the scribe regions. The hybrid formation can be based on wafer-level factors for which crack guides are appropriate in the different regions.

In some embodiments, the process 800 can continue with one or more BEOL processes to form one or more additional layers of circuitry on the wafer. The additional layers can be at least partially coplanar with the crack guides. In some embodiments, the BEOL processes used to form the crack guides can simultaneously form one or more BEOL structures (e.g., metallization lines, routing structures, and the like) over the wafer to form the additional layer(s).

At block 810, the process 800 includes stealth dicing and grinding the wafer. As discussed above, the stealth dicing process can include directing a laser (or other suitable energy beam) at the back side of the wafer to generate stress regions and/or propagate one or more cracks through the wafer. In some embodiments, the stealth dicing process can also include applying one or more stress forces to the wafer to help drive the propagation of the crack(s). Because stealth dicing relies on propagating cracks (e.g., as opposed to mechanically or chemically cutting the wafer), the stealth dicing process can singulate dies (or other suitable components) in the wafer with relatively little clearance between the components. The crack guides can help maintain that low clearance as the circuitry layers on the wafer become thicker to meet demands for increased performance for each individual component. In particular, by attracting the cracks through desired regions, the crack guides can help mitigate the amount that the crack will meander while propagating through the circuitry layers. Once the crack has propagated through the wafer, the process 800 can back-grind the wafer to thin the overall wafer.

At block 812, the process 800 includes singulating the dies (or other suitable components) in the wafer. After the steal dicing and back-grinding, singulating the dies can include removing a carrier film and/or carrier wafer, pulling the dies apart, and/or picking one or more dies out of the wafer. Examples of results of the process 800 are illustrated in FIGS. 6B and 7. The resulting dies (or other suitable components) can then be stacked and/or attached to a package substrate and/or otherwise included into a semiconductor device.

FIG. 8B is a flow diagram of a process 820 for manufacturing a semiconductor die in accordance with some embodiments of the present technology. The process 820 can be implemented by one or more manufacturing apparatuses to complete production of semiconductor dies (or other suitable components) in a wafer-level process. The process 820 begins at block 822 by forming one or more circuitry layers on individual wafers. The circuitry layers formed on individual wafers can include a CMOS circuitry layer, an array circuitry layer, a BEOL circuitry layer, and/or any other circuitry layers. The BEOL circuitry layer (and any other suitable layer) can be formed with crack attraction features (e.g., the plurality of isolated lines 642 and gaps 646 of FIG. 6B and/or the isolated lines 742 of FIG. 7).

At block 824, the process 820 includes stacking and bonding the wafers to formed a stacked wafer structure. Stacking the wafers can include aligning corresponding conductive structures (e.g., segments of a through substrate via, bond pads, and/or the like) to help ensure the layers of the stacked wafer are interconnected. Once aligned, the wafers can be bonded by a hybrid bonding process (e.g., forming a metal-metal bond between the conductive structures and a direct bond between dielectric surfaces), an annealing process (e.g., forming a metal-metal bond), a reflow process, and/or any other suitable bonding process. In some embodiments, the result of the process 820 after block 824 is a complete stacked wafer (e.g., the wafer 600 illustrated in FIG. 6B) that includes crack attraction features. In some embodiments, the result of the process 820 after block 824 is a wafer ready for one or more final layers of processing (e.g., the wafer provided at block 802 of FIG. 8A).

At optional block 826, the process 800 includes forming one or more crack attraction features on a surface of the stacked wafer. The process 820 can implement optional block 826 when none of the individual wafers in the stacked wafer included crack attraction features (e.g., when none of the circuitry layers formed separately was a BEOL layer, when trenches are being used to attract cracks, and the like) and/or when an additional layer of crack attraction features is desired. The process 820 at optional block 826 can be generally similar to blocks 804-808 of the process 800 discussed above. For example, the process 820 can include depositing one or more temporary layers on an upper surface of the stacked wafer, patterning the temporary layer to form two or more isolated lines, and forming the crack attraction features between the isolated lines.

At block 828, the process 820 includes stealth dicing and grinding the stacked wafer. As discussed above, the stealth dicing process can include directing a laser (or other suitable energy beam) at the back side of the wafer to generate stress regions and/or propagate one or more cracks through the wafer and/or applying one or more stress forces to the wafer to help drive the propagation of the crack(s). Once one or more cracks have propagated through the stacked wafer, the process 820 can back-grind the stacked wafer to thin the overall stacked wafer.

At block 830, the process 820 includes singulating the dies (or other suitable components) in the stacked wafer. As discussed above, singulating the dies can include removing a carrier film and/or carrier wafer, pulling the dies apart, and/or picking one or more dies out of the wafer. Examples of results of the process 820 are illustrated in FIGS. 6B and 7. The resulting dies (or other suitable components) can then be stacked and/or attached to a package substrate and/or otherwise included into a semiconductor device.

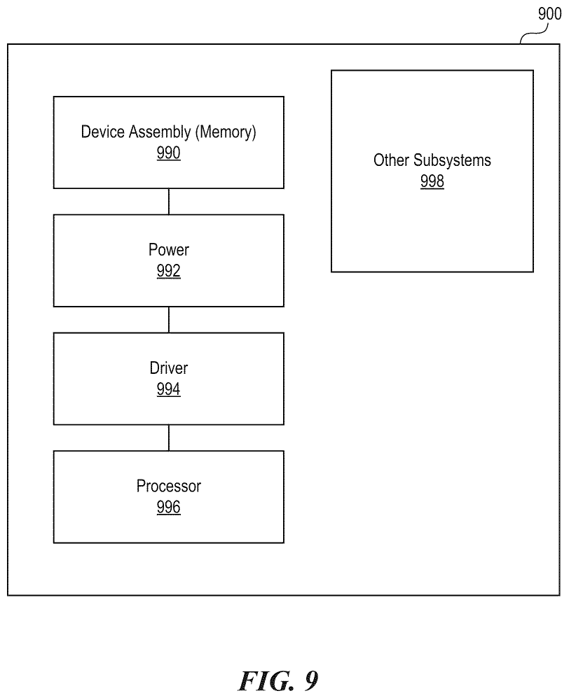

FIG. 9 is a schematic view of a system that includes a semiconductor die assembly configured in accordance with embodiments of the present technology. That is, the semiconductor device assemblies discussed above can be incorporated into any of a myriad of larger and/or more complex systems, a representative example of which is system 900 shown schematically in FIG. 9. The system 900 can include a memory 990 (e.g., SRAM, DRAM, flash, and/or other memory devices), a power supply 992, a drive 994, a processor 996, and/or other subsystems or components 998. Semiconductor dies singulated using processes of the type discussed above with reference to FIGS. 2-7 can be included in any of the elements shown in FIG. 9. Purely by way of example, the semiconductor dies discussed with reference to FIGS. 6B and 7 can be deployed in the memory 990 (e.g., in a managed NAND for us in various consumer electronics, automotive electronics, and the like; an SSD package; and/or any other suitable memory device).

The resulting system 900 can be configured to perform any of a wide variety of suitable computing, processing, storage, sensing, imaging, and/or other functions. Accordingly, representative examples of the system 900 include, without limitation, computers and/or other data processors, such as desktop computers, laptop computers, Internet appliances, hand-held devices (e.g., palm-top computers, wearable computers, cellular or mobile phones, automotive electronics, personal digital assistants, music players, etc.), tablets, multi-processor systems, processor-based or programmable consumer electronics, network computers, and minicomputers. Additional representative examples of the system 900 include lights, cameras, vehicles, etc. With regard to these and other examples, the system 900 can be housed in a single unit or distributed over multiple interconnected units, e.g., through a communication network. The components of the system 900 can accordingly include local and/or remote memory storage devices and any of a wide variety of suitable computer-readable media.

From the foregoing, it will be appreciated that specific embodiments of the technology have been described herein for purposes of illustration, but well-known structures and functions have not been shown or described in detail to avoid unnecessarily obscuring the description of the embodiments of the technology. To the extent any material incorporated herein by reference conflicts with the present disclosure, the present disclosure controls. Where the context permits, singular or plural terms may also include the plural or singular term, respectively. Moreover, unless the word “or” is expressly limited to mean only a single item exclusive from the other items in reference to a list of two or more items, then the use of “or” in such a list is to be interpreted as including (a) any single item in the list, (b) all of the items in the list, or (c) any combination of the items in the list. Furthermore, as used herein, the phrase “and/or” as in “A and/or B” refers to A alone, B alone, and both A and B. Additionally, the terms “comprising,” “including,” “having,” and “with” are used throughout to mean including at least the recited feature(s) such that any greater number of the same features and/or additional types of other features are not precluded. Further, the terms “generally”, “approximately,” and “about” are used herein to mean within at least within 10 percent of a given value or limit. Purely by way of example, an approximate ratio means within ten percent of the given ratio.

From the foregoing, it will also be appreciated that various modifications may be made without deviating from the disclosure or the technology. For example, although described primarily herein in the context of forming each layer of circuitry on top of an existing layer, it will be understood that alternative processes are possible. For example, as discussed with respect to FIG. 8B, one or more layers of circuitry can be manufactured in separate wafer that are then stacked and bonded together to form a stacked wafer. The stacked wafer can then be singulated according to any of the techniques discussed herein. The stacked wafer configuration can accelerate the manufacturing process the semiconductor dies because each wafer can be manufactured at the same time (e.g., rather than sequentially when forming layers on top of each other), then bonded and singulated. Additionally, or alternatively, the stacked wafer configuration can enable relatively large wafer stacks (e.g., having five, ten, fifty, one hundred, five hundred, one thousand, or any other suitable number of circuitry layers) to be formed in an efficient manner, then singulated into separate dies. In addition, one of ordinary skill in the art will understand that various components of the technology can be further divided into subcomponents, or that various components and functions of the technology may be combined and integrated. For example, although the crack attraction features have been discussed herein primarily as being formed in a BEOL layer of circuitry, the technology is not so limited. The crack attraction features can be formed in any other suitable layers of circuitry in addition to (or in alternative to) in a BEOL layer. The additional layers with crack attraction features can further help propagate cracks through the wafer along a straight (or generally straight) singulation line. Additionally, or alternatively, the other layers with the crack attraction features can allow the wafer to omit a BEOL layer (e.g., for stacked wafers with hundreds of circuitry layers). In addition, certain aspects of the technology described in the context of particular embodiments may also be combined or eliminated in other embodiments.

Furthermore, although advantages associated with certain embodiments of the technology have been described in the context of those embodiments, other embodiments may also exhibit such advantages, and not all embodiments need necessarily exhibit such advantages to fall within the scope of the technology. Accordingly, the disclosure and associated technology can encompass other embodiments not expressly shown or described herein.

We claim:

1. A method for singulating semiconductor dies from a wafer, the method comprising:
forming a metallic layer on an upper surface of the wafer and over at least a portion of planned scribe regions of the wafer;
patterning the metallic layer to form a plurality of isolated lines over the planned scribe regions of the wafer, wherein adjacent isolated lines in the plurality of isolated lines are separated by a distance;
depositing a passivation material over the plurality of isolated lines, wherein the distance between each of the adjacent isolated lines small enough to create a gap in the passivation material between each of the adjacent isolated lines; and
stealth dicing the planned scribe regions of the wafer, wherein stealth dicing includes:
directing a laser toward a lower surface of the wafer to form one or more stress regions proximate the lower surface along the planned scribe regions; and
causing one or more cracks to propagate from the one or more stress regions toward the plurality of isolated lines on the upper surface of the wafer.

2. The method of claim 1, further comprising etching the passivation material and at least a portion of the upper surface of the wafer to form a trench in the upper surface between each of the adjacent isolated lines.

3. The method of claim 1, further comprising:
depositing a polyimide over at least a portion of the passivation material corresponding to the plurality of isolated lines; and
etching the passivation material not covered by the polyimide.

4. The method of claim 1 wherein the upper surface of the wafer has a plurality of die regions, wherein the planned scribe regions are positioned in a grid shape around the plurality of die regions, and wherein the method further comprises forming one or more metallization layers on the upper surface of the wafer and over the plurality of die regions.

5. The method of claim 4 wherein at least one of the one or more metallization layers is coplanar with at least a portion of the plurality of isolated lines.

6. The method of claim 1 wherein the distance between each of the adjacent isolated lines is between 2 micrometers and 4 micrometers.

7. The method of claim 1 wherein the planned scribe regions have a width, and wherein the plurality of isolated lines are positioned over about 60 percent of the width.

8. A semiconductor device, comprising:
a base substrate having an upper surface that includes a central region and a peripheral region;
a circuitry layer carried by the central region of the upper surface, wherein the circuitry layer includes one or more metallization layers establishing signal route lines for the semiconductor device; and
one or more isolated lines carried by the peripheral region of the upper surface, wherein the one or more isolated lines are at least partially coplanar with the circuitry layer.

9. The semiconductor device of claim 8 wherein the one or more isolated lines includes two or more isolated lines, wherein the two or more isolated lines are positioned in a passivation layer carried by the upper surface, and wherein the passivation layer includes a gap positioned between each pair of adjacent isolated lines in the two or more isolated lines.

10. The semiconductor device of claim 9 wherein the passivation layer further includes a concave shape along at least a portion of an outer sidewall of the passivation layer.

11. The semiconductor device of claim 8 wherein the one or more isolated lines includes two or more isolated lines, wherein the circuitry layer is a third circuitry layer, and wherein the semiconductor device further comprises:
a first circuitry layer carried by the upper surface of the base substrate beneath the third circuitry layer; and
a second circuitry layer carried by the upper surface of the base substrate over the first circuitry layer and beneath the third circuitry layer, wherein the second circuitry layer includes a top surface, wherein the top surface of the second circuitry layer includes one or more trenches positioned between each pair of adjacent isolated lines in the two or more isolated lines.

12. The semiconductor device of claim 11 wherein the top surface of the second circuitry layer further includes a portion of a trench along a peripheral-most edge of the second circuitry layer.

13. The semiconductor device of claim 8 wherein the circuitry layer is an uppermost circuitry layer, wherein the semiconductor device further comprises a second uppermost circuitry layer, wherein the second uppermost circuitry layer includes one or more sacrificial components, and wherein the one or more isolated lines are at least partially vertically aligned with the sacrificial components.

14. The semiconductor device of claim 8 wherein none of the one or more isolated lines is electrically coupled to another structure in the semiconductor device.

15. The semiconductor device of claim 8 wherein the one or more isolated lines includes two or more isolated lines, and wherein each pair of adjacent isolated lines in the two or more isolated lines is spaced apart by a distance between 2 micrometers and 4 micrometers.

16. A semiconductor wafer, comprising:
a base substrate having an upper surface that includes a plurality of scribe regions forming a grid on the upper surface and a circuitry region in each open location in the grid;
a plurality of circuitry layers carried by the upper surface of the base substrate, wherein the plurality of circuitry layers form a semiconductor die in each open location in the grid; and
a plurality of isolated lines carried by the upper surface of the base substrate over at least a portion of the plurality of scribe regions.

17. The semiconductor wafer of claim 16, further comprising a crack extending from a lower surface of the base substrate to a top surface an uppermost circuitry layer from the plurality of circuitry layers and between two adjacent isolated lines from the plurality of isolated lines.

18. The semiconductor wafer of claim 16 wherein the plurality of isolated lines is at least partially coplanar with an uppermost circuitry layer from the plurality of circuitry layers.

19. The semiconductor wafer of claim 16 wherein the plurality of circuitry layers includes an uppermost circuitry layer and a second uppermost circuitry layer, wherein the plurality of isolated lines is carried by the second uppermost circuitry layer, and wherein a top surface of the second uppermost circuitry layer includes a trench positioned between each pair of adjacent isolated lines from the plurality of isolated lines.

20. The semiconductor wafer of claim 16 wherein each of the plurality of isolated lines is positioned in a passivation material, and wherein the passivation material includes a gap positioned between each pair of adjacent isolated lines in the plurality of isolated lines.
